(19) United States
(12) Patent Application Publication
(10) Pub. No.: US 2024/0032345 A1
(43) Pub. Date: Jan. 25, 2024

(54) ARRAY SUBSTRATE, MANUFACTURING METHOD OF ARRAY SUBSTRATE, AND DISPLAY PANEL

(71) Applicants: WUHAN CHINA STAR OPTOELECTRONICS TECHNOLOGY CO., LTD., Wuhan (CN); WUHAN CHINA STAR OPTOELECTRONICS SEMICONDUCTOR DISPLAY TECHNOLOGY CO., LTD, Wuhan (CN)

(72) Inventor: Ao WANG, Wuhan (CN)

(73) Assignees: WUHAN CHINA STAR OPTOELECTRONICS TECHNOLOGY CO., LTD., Wuhan (CN); WUHAN CHINA STAR OPTOELECTRONICS SEMICONDUCTOR DISPLAY TECHNOLOGY CO., LTD, Wuhan (CN)

(21) Appl. No.: 17/598,276

(22) PCT Filed: Jul. 26, 2021
(86) PCT No.: PCT/CN2021/108390

§ 371 Date: Sep. 26, 2021

(30) Foreign Application Priority Data
Jun. 11, 2021 (CN) 202110653373.9

(51) Int. Cl. H10K 59/122; H10K 59/12

(52) U.S. Cl. CPC H10K 59/122; H10K 59/1201

(57) ABSTRACT

An array substrate, a manufacturing method of the array substrate, and a display panel are provided. The array substrate includes photo spacers disposed on the pixel definition sections; and a protective layer at least disposed on the photo spacers. Wherein, a material of the protective layer is an inorganic material. The protective layer has a characteristic of high hardness, which can prevent the photomask from scratching the photo spacers to generate detritus and foreign matter in an evaporation process, thereby remedying problems of poor display and decrement of service life in current display panels.

### BACKGROUND OF INVENTION

### Field of Invention

The present application relates to a field of display, and specifically to an array substrate, a manufacturing method of the array substrate, and a display panel.

### Description of Prior Art

Organic light-emitting diode (OLED) display panels have been widely used in electronic products such as mobile phones, notebooks, etc. In organic light-emitting display panels, evaporation is needed to form light-emitting devices from organic light-emitting materials. An evaporation process of the organic light-emitting materials is illustrated in FIG. 1. An array substrate includes a substrate 11 and an array composite layer 12. Photo spacers are disposed on the array composite layer 12. During the evaporation process, the array substrate 10 is disposed upside down, a photomask 1000 is located under the array substrate 10, and the photo spacers 14 contact to the photomask 1000, so that the photomask contacting and damaging the array composite layer 12 is prevented. However, during the evaporation process, the photomask 1000 needs to be moved relative to the array substrate 10 to complete alignment actions. At this time, as illustrated by a dotted-line frame A in FIG. 1, the photomask can scratch the photo spacers 14, and detritus and foreign matter 1411 are formed. The foreign matter 1411 attaching to the array substrate 10 causes poor display, such as pixel failure, and even affects encapsulation performance of a subsequent encapsulation layer, resulting in decrement of service life of the organic light-emitting display panels.

### SUMMARY OF INVENTION

In embodiments of the present application, by forming a protective layer made of inorganic materials on surfaces of photo spacers, a problem of forming detritus and foreign matter due to the photomask scratching the photo spacers in the evaporation process is solved, thereby solving problems of poor display and decrement of service life incurred by the detritus and the foreign matter.

Embodiments of the present application provides an array substrate, including:
a substrate;
an array composite layer disposed on the substrate; the array composite layer includes a pixel definition layer, the pixel definition layer includes a plurality of pixel definition sections and openings between adjacent pixel definition sections;
photo spacers disposed on the pixel definition sections; and
a protective layer at least disposed on the photo spacers and disposed steered clear of the openings,
wherein a material of the protective layer is an inorganic material.

Correspondingly, one embodiment of the present application provides a manufacturing method of the array substrate, including following manufacturing steps:
step S100: providing a pending-processed array substrate, wherein the pending-processed array substrate includes a substrate, an array composite layer, and photo spacers, the array composite layer is disposed on the substrate, the array composite layer includes a pixel definition layer, the pixel definition layer includes a plurality of pixel definition sections and openings between adjacent pixel definition sections, and the photo spacers are disposed on the pixel definition sections;
step S200: forming a protective layer, and forming the protective layer on the pixel definition sections, the photo spacers, and the openings, wherein a material of the protective layer is an inorganic material;
step S300: forming a patterned photoresist, wherein the patterned photoresist includes opening holes, and the opening holes expose the openings;
step S400: performing a patterning process on the protective layer, removing the protective layer in the openings by preforming a patterning process on the protective layer through an etching process; and
a step S500: removing the photoresist.

Correspondingly, one embodiment of the present application further provides a display, including an array substrate. Wherein, the array substrate includes:
a substrate;
an array composite layer disposed on the substrate; the array composite layer includes a pixel definition layer, the pixel definition layer includes a plurality of pixel definition sections and openings between adjacent pixel definition sections;
photo spacers disposed on the pixel definition sections; and
a protective layer at least disposed on the photo spacers and disposed steered clear of the openings,
wherein a material of the protective layer is an inorganic material;
wherein the display panel includes light-emitting devices disposed in the openings and an encapsulation layer disposed on the light-emitting devices.

In the embodiments of the present application, the array substrate, the manufacturing method of the array substrate, and the display panel are provided. By forming the protective layer made of inorganic materials on surfaces of photo spacers, the protective layer made of inorganic materials has a characteristic of high hardness, which can prevent the photomask from scratching the photo spacers to generate detritus and foreign matter in the evaporation process, thereby remedying problems of poor display and decrement of service life in current display panels.

### DESCRIPTION OF DRAWINGS

To more clearly illustrate embodiments or the technical solutions of the present application, the accompanying figures of the present application required for illustrating embodiments or the technical solutions of the present application will be described in brief. Obviously, the accompanying figures described below are only part of the embodiments of the present application, from which figures those skilled in the art can derive further figures without making any inventive efforts.

FIG. 1 is a schematic diagram of a process of evaporation processes.

FIG. 2 is a first schematic diagram of an array substrate provided by one embodiment of the present application.

FIG. 3 is a second schematic diagram of the array substrate provided by one embodiment of the present application.

FIG. 4 is a third schematic diagram of the array substrate provided by one embodiment of the present application.

FIG. 5 is a fourth schematic diagram of the array substrate provided by one embodiment of the present application.

FIG. 6 is a flowchart of a manufacturing method of the array substrate provided by one embodiment of the present application.

FIGS. 7 to 11 are schematic diagrams of manufacturing processes of the manufacturing method of the array substrate provided by one embodiment of the present application.

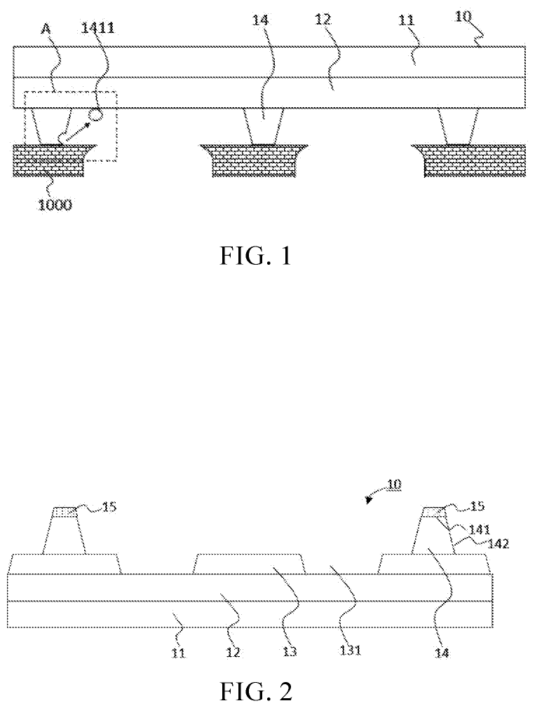

### DETAILED DESCRIPTION OF EMBODIMENTS

The technical solutions in the embodiments of the present application are clearly and completely described in the following with reference to the accompanying drawings in the embodiments of the present application. Obviously, the described embodiments are only part of the embodiments of the present application, but are not all embodiments of the present application. All other embodiments obtained by those skilled in the art based on the embodiments of the present application without creative efforts are within the scope of the present application. Besides, it should be understood that the specific embodiments described herein are merely for describing and explaining the present application and are not intended to limit the present application. In the present application, unless opposite stated, the orientation words used such as “upper” and “lower” generally refer to the upper and lower directions of the device in actual using or working state, and specifically refer to the drawing directions in the drawings, and “inner” and “outer” refer to the outline of the device.

One embodiment of the present application provides an array substrate, including a substrate; an array composite layer disposed on the substrate, wherein the array composite layer includes a pixel definition layer, and the pixel definition layer includes a plurality of pixel definition sections and openings between adjacent pixel definition sections; photo spacers disposed on the pixel definition sections; and a protective layer at least disposed on the photo spacers and disposed steered clear of the openings. Wherein, a material of the protective layer is an inorganic material.

Embodiments of the present application provide the array substrate, a manufacturing method of the array substrate, and a display panel. The details are described respectively as follow. It should be noted that a description order of the following embodiments is not intended to limit a preferred order of the embodiments.

### First Embodiment

Please refer to FIG. 2. FIG. 2 is a first sectional diagram of the array substrate provided by one embodiment of the present application. The array substrate 10 includes a substrate 11. an array composite layer 12, photo spacers 14, and a protective layer 15. The array composite layer 12 is disposed on the substrate 11. The array composite layer 12 includes a pixel definition layer. The pixel definition layer includes a plurality of pixel definition sections 13 and openings 131 between adjacent pixel definition sections 13. The photo spacers 14 are disposed on the pixel definition sections 13. The protective layer is at least disposed on the photo spacers 14 and is disposed steered clear of the openings 131. Wherein, a material of the protective layer 15 is an inorganic material.

Specifically, the substrate 11 can be a rigid substrate or a flexible substrate. When the substrate 11 is the rigid substrate, it can be glass, etc. When the substrate 11 is the flexible substrate, it can be a material such as polyimide (PI), polymethyl methacrylate (PMMA), polycarbonate (PC), etc., which is not limited herein.

Specifically, the array composite layer 12 can include a buffer layer disposed on the substrate 11, a semiconductor layer disposed on the buffer layer, a gate insulation layer disposed on the semiconductor layer, a gate electrode layer disposed on the gate insulation layer, an interlayer insulation layer disposed on the gate electrode layer, a source drain electrode layer disposed on the interlayer insulation layer, a first insulation layer disposed on the source drain electrode layer, and a first electrode disposed on the first insulation layer. The pixel definition layer is defined on the first electrode. The first electrode can be an anode, and the first electrode can be electrically connected to a drain electrode of a thin film transistor.

Specifically, the array composite layer 12 includes the thin film transistor. A structure of the thin film transistor layer is not limited herein. The thin film transistor layer can be a top-gate type thin film transistor, and can also be a bottom-gate type thin film transistor. A material of a semiconductor layer of the thin film transistor can be amorphous silicon, polycrystalline silicon, metal oxide, etc.

Specifically, an organic material can be adopted in the pixel definition layer, and an organic material can be adopted in the photo spacers 14.

In some embodiments, the photo spacers 14 include top surfaces 141 and lateral surfaces 142 away from the pixel definition layer, and the protective layer 15 is disposed on the top surfaces of the photo spacers 14.

Specifically, in this embodiment, the protective layer 15 is only disposed on the top surfaces 141 of the photo spacers 14.

In some embodiments, a thickness of the protective layer 15 is less than a height of the photo spacers 14.

Specifically, the photo spacers 14 are an organic material, which have certain elasticity, and the protective layer 15 is an inorganic material. In the evaporation process, when the photomask and the array substrate 10 are relatively moved and aligned, the photo spacers 14 with elasticity can deform, so that there is a buffering effect between the array substrate 10 and the photomask, which reduces the friction between the array substrate 10 and the photomask. Meanwhile, the protective layer 15 has high hardness, so the protective layer 15 is not easily scratched. Therefore, the protective layer 15 protects the photo spacers 14 and prevents the photo spacers 14 from being scratched to form detritus and foreign matter, thereby remedying problems of poor display and decrement of service life in current display panels.

In some embodiments, a material of the protective layer 15 is any one of silicon nitride or silica.

Specifically, in subsequent encapsulation, when thin film encapsulation is adopted, the thin film encapsulation layer can be a stacked structure of an inorganic layer and an organic layer. The inorganic layer includes any one of silicon nitride or silica. Silicon nitride and silicon silica have good performance of preventing water vapor and oxygen from entering. Any one of the silicon nitride or the silicon oxide is also adopted in the protective layer 15, which can prevent other material from introducing and can prevent new defect.

### Second Embodiment

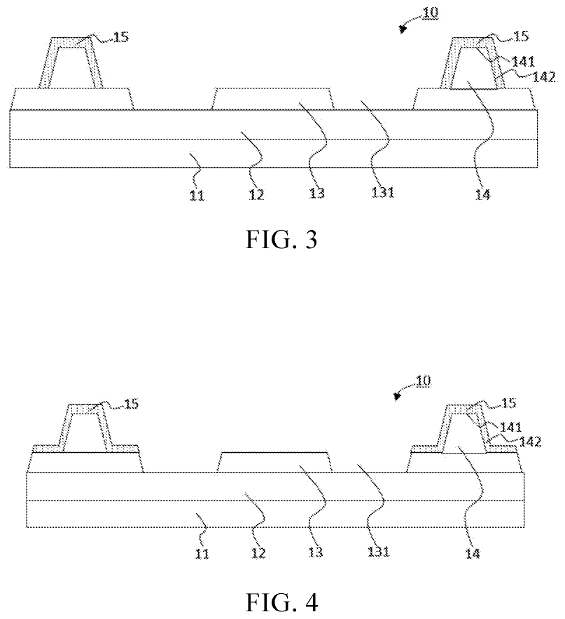

Please refer to FIG. 3. FIG. 3 is a second sectional diagram of the array substrate provided by one embodiment of the present application. Similarity of this embodiment and the first embodiment is not described herein again, and a difference is that a position where the protective layer 15 is disposed is different.

In this embodiment, the protective layer 15 is further disposed on the lateral surfaces 142 of the photo spacers 14.

Specifically, the photo spacers 14 include the top surfaces 141 and the lateral surfaces 142 away from the pixel definition layer, and the protective layer 15 is disposed on the top surfaces 141 and the lateral surfaces 142 of the photo spacers 14.

A size of the array substrate 10 is quite large. In the evaporation processes, when the array substrate 10 is warped or bent, the lateral surfaces of the photo spacers 14 can also contact to the photomask, and the photomask can scratch the top surfaces 141 and the lateral surfaces 142 of the photo spacers 14. By disposing the protective layer 15 on the top surfaces 141 and the lateral surfaces 142 of the photo spacers 14, the photo spacers 14 can be protected better. Therefore, the protective layer 15 protects the photo spacers 14 and prevents the photo spacers 14 from being scratched to form detritus and foreign matter, thereby remedying problems of poor display and decrement of service life in current display panels.

### Third Embodiment

Please refer to FIG. 4. FIG. 4 is a third sectional diagram of the array substrate provided by one embodiment of the present application. Similarity of this embodiment and the first embodiment is not described herein again, and a difference is that a position where the protective layer 15 is disposed is different.

In this embodiment, the protective layer 15 is further disposed on a surface of the protective section 13.

Specifically, the photo spacers 14 include the top surfaces 141 and the lateral surfaces 142 away from the pixel definition layer, and the protective layer 15 is disposed on the top surfaces 141 and the lateral surfaces 142 of the photo spacers 14 and is also disposed on the surface of the pixel definition section 13.

The size of the array substrate 10 is quite large. In the evaporation processes, when the array substrate 10 is warped or bent, the lateral surfaces of the photo spacers 14 and the surface of the pixel definition section 13 can also contact to the photomask, and the photomask can scratch the top surfaces 141 and the lateral surfaces 142 of the photo spacers 14 and the surface of the pixel definition section 13. By disposing the protective layer 15 on the top surfaces 141 and the lateral surfaces 142 of the photo spacers 14 and on the surface of the pixel definition section 13, the photo spacers 14 and the pixel definition section 13 can be protected better. Therefore, the protective layer 15 protects the photo spacers 14 and the pixel definition section 13 and prevents the photo spacers 14 and the pixel definition section 13 from being scratched to form detritus and foreign matter, thereby remedying problems of poor display and decrement of service life in current display panels.

Meanwhile, the surface of the pixel definition section 13 covers the protective layer, and the protective layer 15 can block entrance of water vapor and oxygen, which increases service life of the display panel.

### Fourth Embodiment

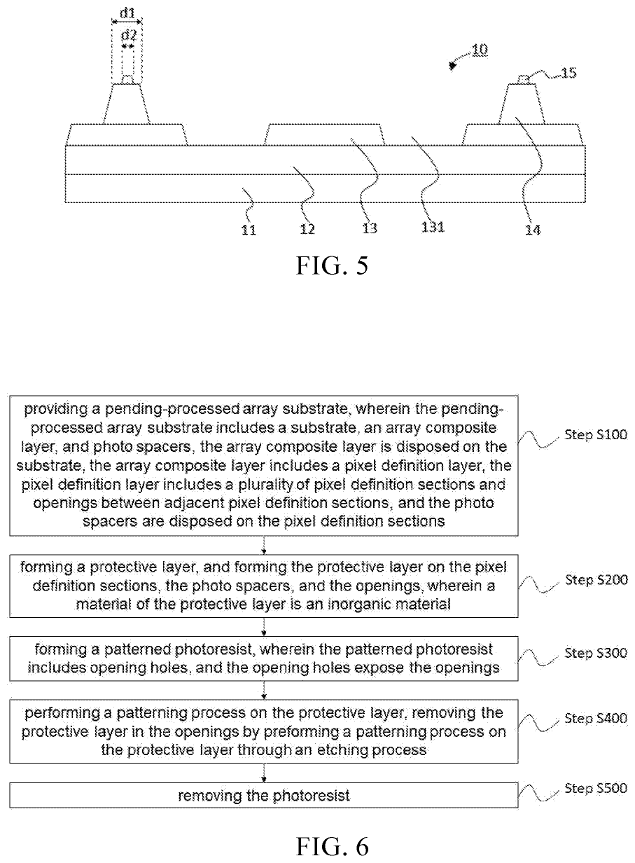

Please refer to FIG. 5. FIG. 5 is a fourth sectional diagram of the array substrate provided by one embodiment of the present application. Similarity of this embodiment and the first embodiment is not described herein again, and a difference is that a size of the disposed protective layer 15 is different.

A length d1 of the top surfaces of the photo spacers 14 is longer than a length d2 of the protective layer 15 on the top surfaces 141, and the protective layer 15 is located at central positions of the top surfaces 141.

Specifically, the protective layer 15 is only disposed at the central positions of the top surfaces 141 of the photo spacers 14, and the length d2 of the protective layer 15 is shorter than the length d1 of the top surfaces 141. When a shape the photo spacers 14 is circular, or a shape of the protective layer 15 is circular, the length d1 refers to a diameter of the top surfaces 141, and the length d2 refers to a diameter of the protective layer 15.

Specifically, the protective layer 15 is only disposed at the central positions of the top surfaces 141 of the photo spacers 14, which can decrease a contact area between the photo spacers 14 and the photomask, thereby reducing friction between the array substrate and the photomask. Therefore, detritus and foreign matter due to the photo spacers 14 being scratched are reduced and prevented, thereby remedying problems of poor display and decrement of service life in current display panels.

### Fifth Embodiment

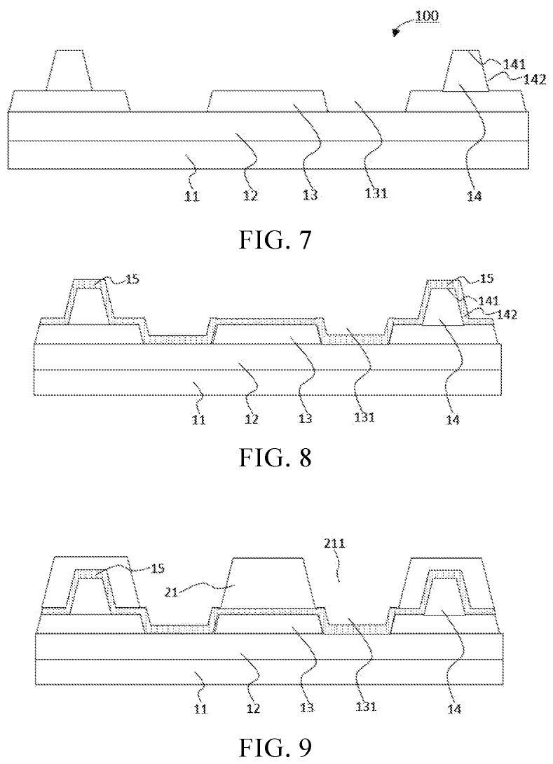

Please refer to FIG. 6 and FIGS. 7 to 11. FIG. 6 is a flowchart of a manufacturing method of the array substrate provided by one embodiment of the present application. FIGS. 7 to 11 illustrate schematic diagrams of manufacturing processes of the manufacturing method of the array substrate provided by one embodiment of the present application. The manufacturing method of the array substrate includes a step S100, a step S200, a step S300, a step S400, and a step S500.
Step S100: providing a pending-processed array substrate, wherein the pending-processed array substrate includes a substrate, an array composite layer, and photo spacers, the array composite layer is disposed on the substrate, the array composite layer includes a pixel definition layer, the pixel definition layer includes a plurality of pixel definition sections and openings between adjacent pixel definition sections, and the photo spacers are disposed on the pixel definition sections,

Specifically, as illustrated in FIG. 7, the pending-processed array substrate 100 includes the substrate 11, the array composite layer 12, and the photo spacers 14, the array composite layer 12 is disposed on the substrate 11, the array composite layer 12 includes the pixel definition layer, the pixel definition layer includes the plurality of pixel definition sections 13 and the openings 131 between adjacent pixel definition sections 13, and the photo spacers 14 are disposed on the pixel definition sections 13.
Step S200: forming a protective layer, and forming the protective layer 15 on the pixel definition sections, the photo spacers 14, and the openings 131, wherein, a material of the protective layer 15 is an inorganic material.

Specifically, as illustrated in FIG. 8, the whole-face protective layer 15 is formed on the pixel definition sections, the photo spacers 14, and the openings 131.
Step S300: forming a patterned photoresist 21, wherein the patterned photoresist 21 includes opening holes 211, and the opening holes 211 expose the openings 131.

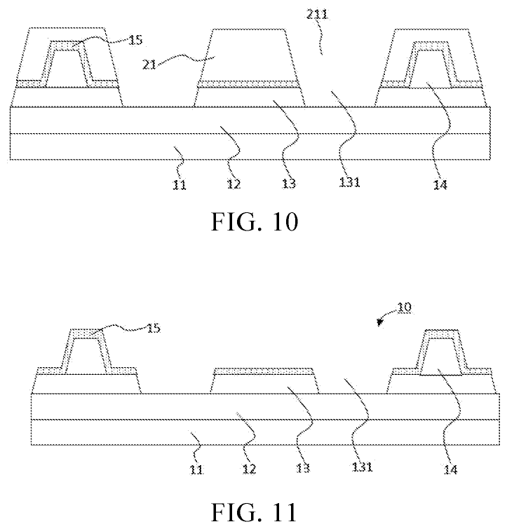

Specifically, as illustrated in FIG. 9, at first, the whole-surface photoresist 21 is formed to cover the pixel definition layer, the photo spacers 14, and the openings 131, and then, the photoresist 21 is patterned by processes such as exposure and development to remove the photoresist corresponding to a part where the protective layer 15 does not need to be retained.
Step S400: as illustrated in FIG. 10, performing a patterning process on the protective layer 15, and removing the protective layer 15 in the openings by preforming a patterning process on the protective layer through an etching process.
Step S500: as illustrated in FIG. 11, removing the photoresist.

In one embodiment of the present application, a material of the protective layer 15 is any one of silicon nitride or silica.

Specifically, in subsequent encapsulation, when thin film encapsulation is adopted, the thin film encapsulation layer can be a stacked structure of an inorganic layer and an organic layer. The inorganic layer includes any one of silicon nitride or silica. Silicon nitride and silicon silica have good performance of preventing water vapor and oxygen from entering. Any one of the silicon nitride or the silicon oxide is also adopted in the protective layer 15, which can prevent other material from introducing and can prevent new defect.

It should be noted that in the array substrate 10, the protective layer 15 can be disposed at different positions, and the position where the protective layer 15 is disposed can refer to the aforesaid embodiments. Redundant description is not mentioned herein again.

This embodiment of the present application has the same beneficial effects as the aforesaid embodiments, and redundant description is not mentioned herein again.

### Sixth Embodiment

One embodiment of the present disclosure further provides a display panel, includes the array substrate 10 of any aforesaid embodiment. The display panel further includes light-emitting devices disposed in the openings 131 and an encapsulation layer disposed on the light-emitting devices.

Specifically, the light-emitting devices can be organic light-emitting devices, which are not limited herein. The encapsulation layer can be a thin-film encapsulation layer or a method of cover-plate encapsulation, which is not limited herein.

The array substrate, the manufacturing method of the array substrate, and the display panel provided by the embodiments of the present application are described in detail above. This article uses specific cases for describing the principles and the embodiments of the present application, and the description of the embodiments mentioned above is only for helping to understand the method and the core idea of the present application. Meanwhile, for those skilled in the art, will have various changes in specific embodiments and application scopes according to the idea of the present application. In summary, the content of the specification should not be understood as limit to the present application.

1. An array substrate, comprising:
a substrate;
an array composite layer disposed on the substrate; wherein the array composite layer comprises a pixel definition layer, and the pixel definition layer comprises a plurality of pixel definition sections and openings between adjacent pixel definition sections;
photo spacers disposed on the pixel definition sections; and
a protective layer at least disposed on the photo spacers and disposed steered clear of the openings,
wherein a material of the protective layer is an inorganic material.

2. The array substrate as claimed in claim 1, wherein the photo spacers comprise top surfaces and lateral surfaces away from the pixel definition layer, and
the protective layer is disposed on the top surfaces of the photo spacers.

3. The array substrate as claimed in claim 2, wherein the protective layer is disposed on the lateral surfaces of the photo spacers.

4. The array substrate as claimed in claim 3, wherein the protective layer is disposed on surfaces of the pixel definition sections.

5. The array substrate as claimed in claim 2, wherein a length of the top surfaces is greater than a length of the protective layer on the top surfaces, and
the protective layer is located at central positions of the top surfaces.

6. The array substrate as claimed in claim 1, wherein a thickness of the protective layers is less than a height of the photo spacers.

7. The array substrate as claimed in claim 5, wherein a thickness of the protective layer is less than a height of the photo spacers.

8. The array substrate as claimed in claim 6, wherein a material of the protective layers is any of silicon nitride or silica.

9. A manufacturing method of an array substrate, comprising following steps:
providing a pending-processed array substrate, wherein the pending-processed array substrate comprises a substrate, an array composite layer, and photo spacers, the array composite layer is disposed on the substrate, the array composite layer comprises a pixel definition layer, the pixel definition layer comprises a plurality of pixel definition sections and openings between adjacent pixel definition sections, and the photo spacers are disposed on the pixel definition sections;
forming a protective layer, and forming the protective layer on the pixel definition sections, the photo spacers, and the openings, wherein a material of the protective layer is an inorganic material;
forming a patterned photoresist,
wherein the patterned photoresist comprises opening holes, and the opening holes expose the openings;
performing a patterning process on the protective layer,
removing the protective layer in the openings by preforming a patterning process on the protective layer through an etching process; and
removing the patterned photoresist.

10. The manufacturing method of the array substrate as claimed in claim 9, wherein a material of the protective layer is any of silicon nitride or silica.

11. A display panel, comprising an array substrate, wherein the array substrate comprises:
a substrate;
an array composite layer disposed on the substrate; the array composite layer comprises a pixel definition layer, the pixel definition layer comprises a plurality of pixel definition sections and openings between adjacent pixel definition sections;
photo spacers disposed on the pixel definition sections; and
a protective layer at least disposed on the photo spacers and disposed steered clear of the openings,
wherein a material of the protective layer is an inorganic material, and
wherein the display panel comprises light-emitting devices disposed in the openings and an encapsulation layer disposed on the light-emitting devices.

12. The display panel as claimed in claim 11, wherein the photo spacers comprise top surfaces and lateral surfaces away from the pixel definition layer, and the protective layer is disposed on the top surfaces of the photo spacers.

13. The display panel as claimed in claim 12, wherein the protective layer is disposed on the lateral surfaces of the photo spacers.

14. The display panel as claimed in claim 13, wherein the protective layer is disposed on surfaces of the pixel definition sections.

15. The display panel as claimed in claim 12, wherein a length of the top surfaces is greater than a length of the protective layer on the top surfaces, and the protective layer is located at central positions of the top surfaces.

16. The display panel as claimed in claim 11, wherein a thickness of the protective layer is less than a height of the photo spacers.

17. The display panel as claimed in claim 15, wherein a thickness of the protective layer is less than a height of the photo spacers.

18. The display panel as claimed in claim 16, wherein a material of the protective layer is any of silicon nitride or silica.
